(19) United States
(12) Patent Application Publication
(10) Pub. No.: US 2007/0181888 A1
(43) Pub. Date: Aug. 9, 2007

(54) Flip-chip light emitting device

(75) Inventors: Hyun-soo Kim, Hwaseong-si (KR); Jae-hee Cho, Yongin-si (KR)

Correspondence Address: BUCHANAN, INGERSOLL & ROONEY PC, POST OFFICE BOX 1404, ALEXANDRIA, VA, 22313-1404, US

(73) Assignee: Samsung Electro-mechanics Co., Ltd., Suwon-si (KR)

(21) Appl. No.: 11/515,746

(22) Filed: Sep. 6, 2006

(30) Foreign Application Priority Data
Feb. 9, 2006 (KR) 10-2006-0012601

(51) Int. Cl. H01L 33/00

(52) U.S. Cl. 257/79

(57) ABSTRACT

A flip-chip light emitting device including: a substrate; an n-type semiconductor layer formed on a top surface of the substrate; an active layer formed on a top surface of the n-type semiconductor layer; a p-type semiconductor layer formed on a top surface of the active layer; a p-type electrode formed on a top surface of the p-type semiconductor layer; and an n-type electrode formed on an exposed portion of the top surface of the n-type semiconductor layer is provided. The p-type electrode includes: an ohmic contact layer formed with a predetermined width along an edge of the top surface of the p-type semiconductor layer near to the n-type electrode; and a reflective layer covering the ohmic contact layer and a portion of the top surface of the p-type semiconductor layer not covered by the ohmic contact layer.

### CROSS-REFERENCE TO RELATED PATENT APPLICATION

This application claims the benefit of Korean Patent Application No. 10-2006-0012601, filed on Feb. 9, 2006, in the Korean Intellectual Property Office, the disclosure of which is incorporated herein in its entirety by reference.

### BACKGROUND OF THE DISCLOSURE

1. Field of the Disclosure

The present disclosure relates to a flip-chip light emitting device, and more particularly, to a flip-chip light emitting device having a p-type electrode with an improved reflectivity realized by reducing the amount of light absorbed by an ohmic contact layer.

2. Description of the Related Art

Semiconductor light emitting devices, such as light emitting diodes (LEDs), which convert electrical signals into light by exploiting the characteristics of semiconductors, are used in various application fields such as display devices and illumination devices.

Semiconductor light emitting devices are classified into top-emitting light emitting devices and flip-chip light emitting devices according to the direction in which light is emitted from the light emitting device.

Top-emitting light emitting devices emit light through a p-type electrode that forms an ohmic contact with a p-type semiconductor layer. The p-type electrode is generally formed by sequentially stacking a nickel (Ni) layer and a gold (Au) layer on the p-type semiconductor layer. However, the p-type electrode formed of the nickel/gold layers is only semi-transparent, and thus, the top-emitting light emitting devices employing the p-type electrode have low optical efficiency and low luminance.

Flip-chip light emitting devices are structured such that light generated by an active layer is reflected by a reflective p-type electrode formed on a p-type semiconductor layer, and the reflected light is emitted through a substrate. FIG. 1 is a graph illustrating a relationship between the reflectivity of a reflective p-type electrode and the light extraction efficiency of a flip-chip light emitting device. As shown on the graph, the reflectivity of the reflective p-type electrode substantially affects the light extraction efficiency of the flip-chip light emitting device. Accordingly, the reflective p-type electrode is formed of a highly light-reflective material such as silver (Ag), aluminum (Al), or rhodium (Rh). The flip-chip light emitting device employing the reflective p-type electrode can have high optical efficiency and high luminance. However, since the reflective p-type electrode has a high contact resistance on the p-type semiconductor layer, the operating voltage of the light emitting device employing the reflective p-type electrode is large and the characteristics of the light emitting device are unstable.

In order to address these problems, research into electrode materials and electrode structures having low contact resistances and a high reflectances have been carried out.

International Patent Publication No. WO 01/47038 A1 discloses a semiconductor light emitting device having a reflective electrode. In this case, an ohmic contact layer formed of titanium (Ti) or nickel/gold (Ni/Au) is interposed between the reflective electrode and a p-type semiconductor layer, but light loss still occurs because the ohmic contact layer has a high light absorption rate. Accordingly, the disclosed conventional semiconductor light emitting device has the disadvantages of low optical efficiency and low luminance. To overcome these disadvantages, the electrode structure for the semiconductor light emitting device needs to be improved.

### SUMMARY OF THE DISCLOSURE

The present invention may provide a flip-chip light emitting device having a reduced contact resistance between a p-type semiconductor layer and a reflective electrode and an improved optical efficiency.

According to an aspect of the present invention, there is provided a flip-chip light emitting device comprising: a substrate; an n-type semiconductor layer formed on a top surface of the substrate; an active layer formed on a top surface of the n-type semiconductor layer; a p-type semiconductor layer formed on a top surface of the active layer; a p-type electrode formed on a top surface of the p-type semiconductor layer; and an n-type electrode formed on an exposed portion of the top surface of the n-type semiconductor layer, wherein the p-type electrode comprises: an ohmic contact layer formed with a predetermined width along an edge of the top surface of the p-type semiconductor layer near to the n-type electrode; and a reflective layer covering the ohmic contact layer and a portion of the top surface of the p-type semiconductor layer not covered by the ohmic contact layer.

### BRIEF DESCRIPTION OF THE DRAWINGS

The above and other features and advantages of the present invention are illustrated in detailed exemplary embodiments thereof with reference to the attached drawings in which:

FIG. 1 is a graph illustrating a relationship between the reflectivity of a p-type electrode and the light extraction efficiency of a conventional flip-chip light emitting device;

FIG. 2 is a top view of a flip-chip light emitting device according to an embodiment of the present invention;

FIG. 3 is a cross-sectional view of a central cell A of the flip-chip light emitting device of FIG. 2;

FIG. 4 is an equivalent circuit diagram illustrating the resistance structure of the flip-chip light emitting device of FIG. 2;

FIG. 5 is a graph illustrating a relationship between the width of an ohmic contact layer and the resistance of the flip-chip light emitting device of FIG. 2;

FIG. 6 is a graph illustrating a relationship between the width of the ohmic contact layer and a forward voltage applied to flow a current of 20 mA through the flip-chip light emitting device of FIG. 2;

FIG. 7 is a graph illustrating a relationship between the width of the ohmic contact layer and the normalized optical power of the flip-chip light emitting device of FIG. 2; and

FIG. 8 is a cross-sectional view of a flip-chip light emitting device according to another embodiment of the present invention.

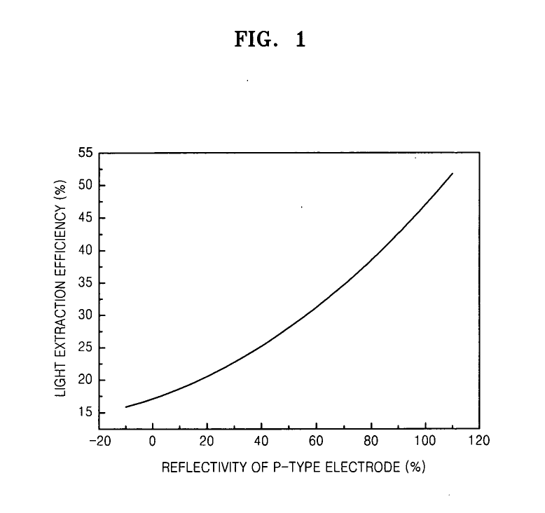

### DETAILED DESCRIPTION OF EXEMPLARY EMBODIMENTS

The present invention will now be described more fully with reference to the accompanying drawings, in which exemplary embodiments of the invention are shown.

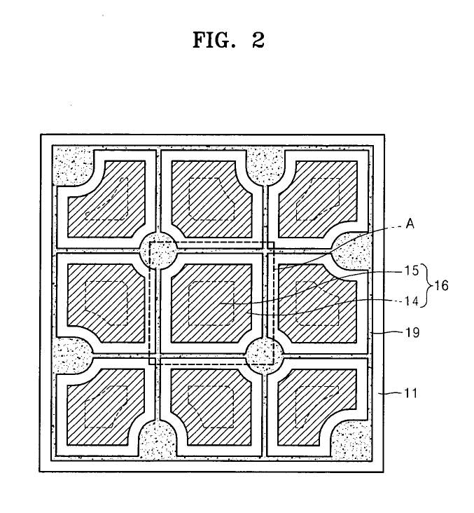

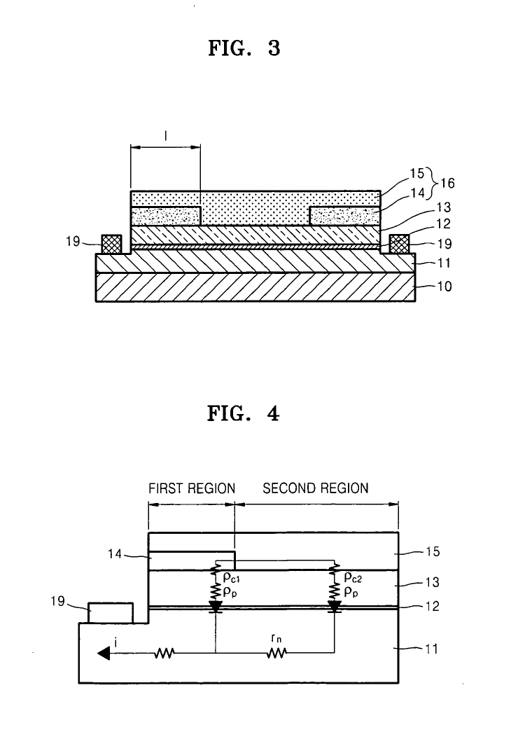

FIG. 2 is a top view of a flip-chip light emitting device according to an embodiment of the present invention and FIG. 3 is a cross-sectional view of a central cell A of the flip-chip light emitting device of FIG. 2. Referring to FIGS. 2 and 3, the flip-chip light emitting device has a plurality of cells that have the same structure and are arranged in a 3×3 array. A substrate 10, an n-type semiconductor layer 11 disposed on the substrate 10, and an n-type electrode 19 disposed on the n-type semiconductor layer 11 can be used. Active layers 12, p-type semiconductor layers 13, and p-type electrodes 16 are arranged in a 3×3 array on the n-type semiconductor layer 11.

The central cell A is formed such that the n-type semiconductor layer 11, one of the active layers 12, one of the p-type semiconductor layers 13, and one of the p-type electrodes 16 are sequentially stacked on a top surface of the substrate 10 and the n-type electrode 19 is formed on an exposed portion of a top surface of the n-type semiconductor layer 11. Here, the flip-chip light emitting device of the present embodiment is characterized by the p-type electrode 16 having an ohmic contact layer 14 that has a predetermined width I and is formed along an edge, where a current crowding effect occurs, of a top surface of the p-type semiconductor layer 13 close to the n-type electrode 19. The flip-chip light emitting device of the present embodiment is also characterized by having a reflective layer 15 that covers the ohmic contact layer 14 and a portion of the p-type semiconductor layer 13 that is not covered by the ohmic contact layer 14. Such a structure may be easily produced by simply modifying the design of a typical mask.

The substrate 10 may be formed of one of the group consisting of sapphire (Al₂O₃), gallium nitride (GaN), silicon carbide (SiC), silicon (Si), and gallium arsenide (GaAs). The n-type semiconductor layer 11 stacked on the top surface of the substrate 10 may be formed of an n-GaN-based III-V nitride semiconductor. The active layer 12 stacked on the top surface of the n-type semiconductor layer 11 may be formed of a GaN-based III-V nitride compound semiconductor such as InₓAl_{y}Ga_{1-x-y}N (0≦x<1, 0≦y≦1, and x+y≦1) containing a predetermined amount of aluminum (Al). The active layer 12 may be formed into a multi quantum well structure or a single quantum well structure. The structure of the active layer 12 does not limit the technical scope of the present invention. The p-type semiconductor layer 13 stacked on a top surface of the active layer 12 may be formed of a p-GaN-based III-V nitride compound semiconductor.

The respective layers may be formed using physical vapor deposition (PVD), chemical vapor deposition (CVD), plasma laser deposition (PLD), dual-type thermal evaporation, or sputtering.

The portion of the n-type semiconductor layer 11 not covered by the active layer 12 and the p-type semiconductor layer 13 is exposed, and the n-type electrode 19 is disposed on the exposed portion of the n-type semiconductor layer 11.

The p-type electrode 16 is formed by sequentially stacking the ohmic contact layer 14 and the reflective layer 15 on the top surface of the p-type semiconductor layer 13.

When a current is injected into the p-type electrode 16, the current crowds into a region near to the n-type electrode 19 as described later, in an effect known as current crowding. The flip-chip light emitting device of the present embodiment uses the current crowding effect to improve light extraction efficiency without significantly increasing an operating voltage. To this end, the ohmic contact layer 14 is formed with a predetermined width I along the edge of the top surface of the p-type semiconductor layer 13 near to the n-type electrode 19, that is, along the region where the current crowding effect occurs.

The ohmic contact layer 14 reduces the contact resistance between the reflective layer 15 and the p-type semiconductor layer 13. The ohmic contact layer 14 may be formed of one of the group consisting of Pd, Pt, Ni, Rh, Ti, Ir, Ru, Ga, ZnNi, and ITO to a thickness ranging from about 1 to 100 A.

The width I of the ohmic contact layer 14 may be in a range from 0.8 Lₛ to 1.2 Lₛ so as to fully cover the region where the current crowding effect occurs. Here, Lₛ denotes a current spreading length that is related to the degree of the current crowding effect. The current crowding effect occurring along the edge of the p-type semiconductor layer 13 is disclosed in “Current Crowding and Optical Saturation Effects in GaInN/GaN Light-Emitting Diodes Grown on Insulating Substrates”, Applied Physics Letters, Vol. 78, pp 33 to 37, 2001. According to the paper, the current crowding effect mainly occurs along the mesa-edge of the top surface of the p-type semiconductor layer 13 near to the n-type electrode 19. In the paper, the current spreading length Lₛ is expressed by

Lₛ=\sqrt{(ρ_{c}+ρₚtₚ)tₙ/ρₙ}. (1)

where ρ_{c} is the contact resistance of the p-type electrode 16, ρₚ is the resistance of the p-type semiconductor layer 13, tₚ is the thickness of the p-type semiconductor layer 13, tₙ is the thickness of the n-type semiconductor layer 11, and ρₙ is the resistance of the n-type semiconductor layer 11.

The reflective layer 15 is stacked on the ohmic contact layer 14 and the portion of the top surface of the p-type semiconductor layer 13 not covered by the ohmic contact layer 14. The reflective layer 15 is formed of a highly light-reflective material, and reflects light generated by the active layer 12. The reflective layer 15 may be formed of one of the group consisting of Ag, Ag₂O, Al, Zn, Ti, Rh, Mg, Pd, Ru, Pt, and Ir to have a metal structure for directly reflecting light.

In the flip-chip light emitting device constructed as above, when a predetermined voltage is applied to the p-type electrode 16 and the n-type electrode 19, electrons of the n-type semiconductor layer 11 and holes of the p-type semiconductor layer 13 gather in the active layer 12 due to the voltage. Then, the electrons and the holes recombine in the active layer 12 to emit light. The emitted light is emitted in every direction including toward and through the p-type semiconductor layer 13. However, part of the light traveling through the p-type semiconductor layer 13 is reflected by the reflective layer 15, and thus most of the light is emitted outwardly through the substrate 10.

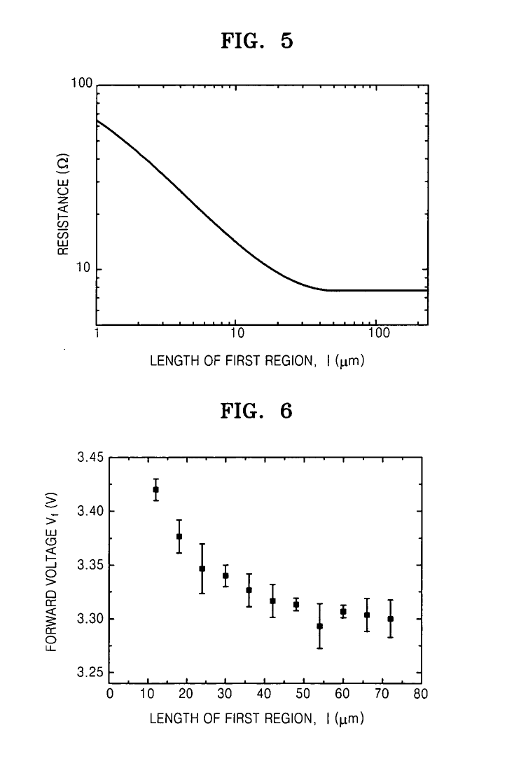

FIG. 4 is an equivalent circuit diagram illustrating the resistance structure of the flip-chip light emitting device of FIG. 2. FIGS. 5 through 7 are graphs illustrating the characteristics of the flip-chip light emitting device of FIG. 2. The operation and effect of the flip-chip light emitting device of FIG. 2 will now be explained with reference to FIGS. 4 through 7.

Referring to FIG. 4, the p-type semiconductor layer 13 is divided into a first region on which the ohmic contact layer 14 is formed and a second region on which the ohmic contact layer 14 is not formed but the reflective layer 15 is directly formed. When a current i is injected into the reflective layer 15, part of the current i flows through the first region and the rest of the current i flows though the second region. That is, the part of the current i 15 flows through the ohmic contact layer 14 to the p-type semiconductor layer 13, and the rest of the current i directly flows to the p-type semiconductor layer 13. The current i passing through the p-type semiconductor layer 13 with the resistance ρₚ flows through the active layer 12 and the n-type semiconductor layer 11 to the n-type electrode 10. Here, the first region has a relatively low contact resistance ρ_{c1}, and the second region has a relatively high contact resistance ρ_{pc2}. The part of the current i passing through the first region passes through a gap between an end of the active layer 12 and the n-type electrode 19. However, the rest of the current i passing through the second region travels a longer distance through the n-type semiconductor layer 11 than the part of the current i passing through the first region, thereby being more affected by the resistance ρₙ of the n-type semiconductor layer 11. Accordingly, the current i injected into the reflective layer 15 tends to flow through the first region to the n-type electrode 19. Accordingly, the overall resistance of the flip-chip light emitting device is closely related to the area of the first region.

FIGS. 5 through 7 are graphs illustrating characteristics obtained from experiments performed on the flip-chip light emitting device of FIG. 2. In this case the n-type semiconductor layer 11 is an n-GaN layer with a thickness of 2.0×10⁻⁴ cm and a resistance of 8.0×10⁻³ Ωcm, the p-type semiconductor layer 13 is a p-GaN layer with a thickness of 1.5×10⁻⁵ cm and a resistance of 2.0 Ωcm, the p-type electrode 16 has a contact resistance of 1.0×10⁻³ Ωcm², and the current spreading length Lₛ of the flip-chip light emitting device is 50 μm according to an embodiment of the present invention.

FIG. 5 illustrates a relationship between the width I of the ohmic contact layer 14 and the resistance of the flip-chip light emitting device. The resistance decreases inversely proportional to the width I of the ohmic contact layer 14, but when the width I of the ohmic contact layer 14 is greater than a specific value, there is no change in the resistance. This is because when the first region exceeds a predetermined level, most of the current i flows through the first region. In other words, when the width I of the ohmic contact layer 14 exceeds the specific value, the ohmic contact layer 14 can no longer reduce a contact resistance due to the current crowding effect. Here, the width I of the ohmic contact layer 14 formed when there is no resistance change corresponds to the current spreading length Lₛ.

FIG. 6 illustrates a relationship between the width I of the ohmic contact layer 14 and a forward voltage V_{f} applied to the flip-chip light emitting device of FIG. 2, according to the current embodiment of the present invention. The forward voltage V_{f} represents the operating voltage required to create a current of 20 mA through the flip-chip light emitting device of the current embodiment. Referring to FIG. 6, the forward voltage V_{f} decreases as the width I of the ohmic contact layer 14 increases, and when the width I of the ohmic contact layer 14 is greater than a specific value, there is no change in the forward voltage V_{f}. This is because, when the width I of the ohmic contact layer 14 exceeds the specific value, there is no change in the resistance as described with reference to FIG. 5. The forward voltage V_{f}, in this instance, is approximately 3.27 V when the ohmic contact layer 14 covers the entire top surface of the p-type semiconductor layer 13, and the forward voltage V_{f} is approximately 3.32 V when the current spreading length Lₛ is 50 μm. The difference between the two operating voltages 3.27 V and 3.32 V is approximately 0.05 V, a slight change.

FIG. 7 is a graph illustrating a relationship between the width I of the ohmic contact layer 14 and the normalized optical power of the flip-chip light emitting device of FIG. 2, according to the current embodiment of the present invention. In this instance, the optical power of the flip-chip light emitting device obtained when the ohmic contact layer 14 covers the entire top surface of the p-type semiconductor layer 13 is defined here as a reference optical power of 1.00. Referring to FIG. 7, the optical power decreases smoothly as the width I of the ohmic contact layer 14 increases. When the width I of the ohmic contact layer 14 exceeds 60 Mm, the optical power begins to decrease sharply. This is because, as the ohmic contact layer 14 becomes wider, the amount of light absorbed by the ohmic contact layer 14 increases and the reflection efficiency of the reflective layer 15 decreases. As can be seen, until the width I of the ohmic contact layer 14 is about the same as the current spreading length Lₛ, the optical power does not decrease significantly.

Referring to FIGS. 5 through 7, the flip-chip light emitting device of FIG. 2, according to the current embodiment of the present invention, has a sufficiently reduced contact resistance and operating voltage realized by partially forming the ohmic contact layer 147 on the top surface of the p-type semiconductor layer 13 along the region where the current crowding effect occurs without forming the ohmic contact layer 14 over the entire top surface of the p-type semiconductor layer 13. Furthermore, the flip-chip light emitting device of FIG. 2 has an improved light extraction efficiency realized by causing the reflective layer 15 to partially contact the p-type semiconductor layer 13 in a direct manner to increase reflection efficiency. In detail, when the width I of the ohmic contact layer 14 is in a range from 0.8 Lₛ to 1.2 Lₛ, the ohmic contact layer 14 can fully cover the region where the current crowding effect occurs, thereby sufficiently reducing the required contact resistance and operating voltage while maintaining reflection efficiency.

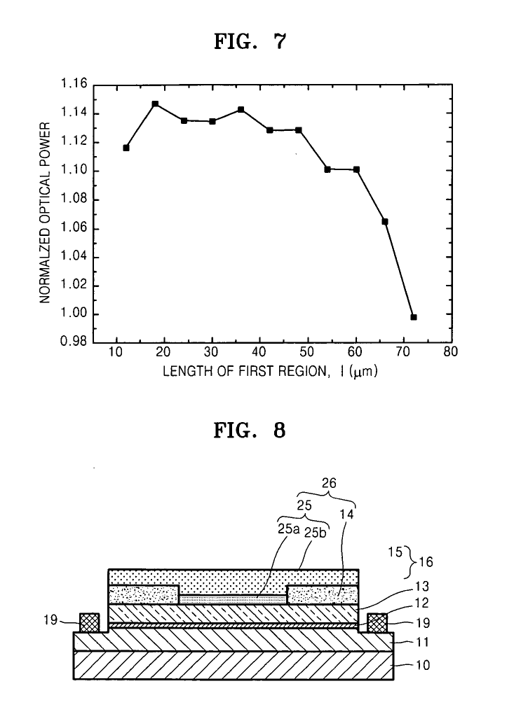

FIG. 8 is a cross-sectional view illustrating a central cell of a flip-chip light emitting device, which includes a plurality of cells arranged in a 3×3 array, according to another embodiment of the present invention. Since the flip-chip light emitting device of FIG. 8 is substantially similar to the flip-chip light emitting device of FIG. 2 except for a reflective layer 25, the same elements as those in FIG. 2 are given the same reference numerals and a detailed description thereof is being omitted.

Referring to FIG. 8, a p-type electrode 26 includes an ohmic contact layer 14 and the reflective layer 25. The ohmic contact layer 14 is formed with a predetermined width along an edge of a top surface of a p-type semiconductor layer 13 close to an n-type electrode 19. The reflective layer 25 covers the ohmic contact layer 14 and a portion of the top surface of the p-type semiconductor layer 13 not covered by the ohmic contact layer 14.

The reflective layer 25 has an omni-directional reflector (ODR) structure formed by sequentially stacking a dielectric layer 25a and a metal layer 25b. The dielectric layer 25a is formed on the portion of the top surface of the p-type semiconductor layer 13 not covered by the ohmic contact layer 14. The metal layer 25b is formed on the ohmic contact layer 14 and a top surface of the dielectric layer 25a. The dielectric layer 25a has a thickness of λ/4n, where λ is the wavelength of emitted light and n is the refractive index of the dielectric layer 25a. The dielectric layer 25a may be formed of one of the group consisting of silicon oxide, silicon nitride, silicon oxynitride, aluminum oxide, lithium fluoride, calcium fluoride, and magnesium fluoride, and the metal layer 25b may be formed of one of the group consisting of Ag, Ag₂O, Al, Zn, Ti, Rh, Mg, Pd, Ru, Pt, and Ir.

Since the dielectric layer 25a is stacked prior to the metal layer 25b, the dielectric layer 25a acts as a highly refractive coating for the metal layer 25b, thereby further improving the reflection efficiency of the reflective layer 25.

Although current crowding can become severe when the ohmic contact layer 14 is formed along the edge of the top surface of the p-type semiconductor layer 13 of a single cell flip-chip light emitting device, since the flip-chip light emitting device is formed in the 3×3 array as shown in FIG. 2, the current crowding effect can be alleviated. However, the flip-chip light emitting device of the present embodiment is not limited to the array structure, and the flip-chip light emitting device may include a single cell, such as cell A (see FIG. 2), or a structure where a plurality of cells are arranged in various forms.

As described above, the flip-chip light emitting device according to the present invention has an improved structure of the p-type electrode realized by modifying the design of a mask, thereby sufficiently reducing the required contact resistance and operating voltage while improving light extraction efficiency.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A flip-chip light emitting device comprising:
a substrate;
an n-type semiconductor layer formed on a top surface of the substrate;
an active layer formed on a top surface of the n-type semiconductor layer;
a p-type semiconductor layer formed on a top surface of the active layer;
a p-type electrode formed on a top surface of the p-type semiconductor layer; and
an n-type electrode formed on an exposed portion of the top surface of the n-type semiconductor layer,
wherein the p-type electrode comprises:
an ohmic contact layer formed with a predetermined width along an edge of the top surface of the p-type semiconductor layer near to the n-type electrode; and
a reflective layer covering the ohmic contact layer and a portion of the top surface of the p-type semiconductor layer not covered by the ohmic contact layer.

2. The flip-chip light emitting device of claim 1, wherein the width I of the ohmic contact layer is in a range from 0.8 Lₛ to 1.2 Lₛ, where Lₛ is a current spreading length defined by
Lₛ=\sqrt{(ρ_{c}+ρₚtₚ)tₙ/ρₙ}.
where ρ_{c} is the contact resistance of the p-type electrode, ρₚ is the resistance of the p-type semiconductor layer, tₚ is the thickness of the p-type semiconductor layer, tₙ is the thickness of the n-type semiconductor layer, and ρₙ is the resistance of the n-type semiconductor layer.

3. The flip-chip light emitting device of claim 1, wherein the ohmic contact layer is formed of one of the group consisting of Pd, Pt, Ni, Rh, Ti, Ir, Ru, Ga, ZnNi, and ITO.

4. The flip-chip light emitting device of claim 1, wherein the reflective layer is formed of one of the group consisting of Ag, Ag₂O, Al, Zn, Ti, Rh, Mg, Pd, Ru, Pt, and Ir.

5. The flip-chip light emitting device of claim 1, wherein the reflective layer has an omni-directional reflector (ODR) structure comprising a dielectric layer and a metal layer.

6. The flip-chip light emitting device of claim 5, wherein the dielectric layer has a thickness of λ/4n, where λ is the wavelength of emitted light and n is the refractive index of the dielectric layer.

7. The flip-chip light emitting device of claim 5, wherein the dielectric layer is formed of one of the group consisting of silicon oxide, silicon nitride, silicon oxynitride, aluminum oxide, lithium fluoride, calcium fluoride, and magnesium fluoride.

8. The flip-chip light emitting device of claim 5, wherein the metal layer is formed of one of the group consisting of Ag, Ag₂O, Al, Zn, Ti, Rh, Mg, Pd, Ru, Pt, and Ir.
